(19) United States
(12) Patent Application Publication
(10) Pub. No.: US 2025/0072164 A1
(43) Pub. Date: Feb. 27, 2025

(54) METHOD OF FORMING INDIUM GALLIUM NITRIDE QUANTUM WELL STRUCTURE

(71) Applicant: NATIONAL SUN YAT-SEN UNIVERSITY, Kaohsiung City (TW)

(72) Inventors: I-KAI LO, Kaohsiung City (TW); CHENG-DA TSAI, Kaohsiung City (TW); YU-CHUNG LIN, Kaohsiung City (TW); YING-CHIEH WANG, Kaohsiung City (TW); MING-CHI CHOU, Kaohsiung City (TW); TING-CHANG CHANG, Kaohsiung City (TW)

(21) Appl. No.: 18/372,795

(22) Filed: Sep. 26, 2023

(30) Foreign Application Priority Data
Aug. 25, 2023 (TW) 112132141

(51) Int. Cl. H01L 33/00

(52) U.S. Cl. CPC H01L 33/0075

(57) ABSTRACT

A method for forming an indium gallium nitride quantum well structure is disclosed. The method includes forming a gallium nitride microdisk on a substrate, with the gallium nitride microdisk having an inverted pyramid form and an end face; and forming multiple quantum well layers on the end face, with each quantum well layer including an indium gallium nitride quantum well and a barrier layer. The indium gallium nitride quantum well is grown at a growth temperature adjusted using a trend equation within a temperature range of 480° C. to 810° C.

### CROSS REFERENCE TO RELATED APPLICATION

The application claims the benefit of Taiwan application serial No. 112132141, filed on Aug. 25, 2023, and the entire contents of which are incorporated herein by reference.

### BACKGROUND OF THE INVENTION

### 1. Field of the Invention

The present invention relates to a method of forming an indium gallium nitride quantum well structure and, more particularly, to a method of forming an indium gallium nitride quantum well structure including a gallium nitride microdisk.

### 2. Description of the Related Art

The development of micro light-emitting diode (micro LED) has attracted much attention for better display effects and lower energy consumption. In previous research, a gallium nitride microdisk (GaN microdisk) manufactured by molecular beam epitaxy is disclosed, which is self-assembled and in a form of an inverted hexagonal pyramid, which can provide a hexagonal three-dimensional c plane as a growth platform for indium gallium nitride quantum wells. Moreover, by adjusting the flow ratio of indium and gallium when forming an indium gallium nitride quantum well, the indium content in the indium gallium nitride quantum well can be controlled, thereby emitting lights of different colors.

However, a manufacturing method that can systematically adjust the growth conditions of indium gallium nitride quantum wells is needed to efficiently manufacture micro LEDs corresponding to lights of different colors. For example, it is desired to set a fixed flow ratio of indium and gallium, and control the indium content by adjusting the growth temperature to cause the indium gallium nitride quantum well to emit lights of different colors. Moreover, due to the lattice mismatch between gallium nitride and indium nitride, an accumulation of anisotropic strain will occur during the epitaxial growth process of indium gallium nitride quantum wells. When the strain in the crystal lattice exceeds a critical value, cracks will occur in the epitaxial film, potentially reducing the grain yield.

Thus, it is necessary to improve the conventional method of forming indium gallium nitride quantum well structures.

### SUMMARY OF THE INVENTION

To solve the above problem, it is an objective of the present invention to provide a method for forming an indium gallium nitride quantum well structure, which involves adjusting the growth temperature of the indium gallium nitride quantum wells to control the indium content, thereby growing indium gallium nitride quantum well grains emitting lights of different colors using a single material.

It is another objective of the present invention to provide a method for forming an indium gallium nitride quantum well structure that can reduce the occurrence of cracks in the quantum well layer due to strain accumulation and improve the quality of the quantum well structures.

As used herein, the term “a”, “an” or “one” for describing the number of the elements and members of the present invention is used for convenience, provides the general meaning of the scope of the present invention, and should be interpreted to include one or at least one. Furthermore, unless explicitly indicated otherwise, the concept of a single component also includes the case of plural components.

A method of forming an indium gallium nitride quantum well structure according to the present invention includes: forming a gallium nitride microdisk on a substrate, with the gallium nitride microdisk having an inverted pyramid form and an end surface; and forming multiple quantum well layers on the end surface, with each quantum well layer including an indium gallium nitride quantum well and a barrier layer. The indium gallium nitride quantum well is grown at a growth temperature in a range of 480° C. to 810° C., and the growth temperature is adjusted using a trend equation.

Thus, the method of forming an indium gallium nitride quantum well structure according to the present invention may involve setting the flow ratio of indium and gallium to a fixed value when forming the indium gallium nitride quantum well, and controlling the indium content in the formed indium gallium nitride quantum well by adjusting the growth temperature, thereby making indium gallium nitride quantum wells emit lights of different colors. Accordingly, the method of forming an indium gallium nitride quantum well structure according to the present invention provides an effect of growing indium gallium nitride quantum well grains emitting lights of different colors using a single material.

In an example, the trend equation is

$$[ In ] = y ( T ) = {y}_{0} + {α}_{In} * exp [ - {ε}_{i} / {k}_{B} * ( T - {T}_{0} ) ] ,$$

in which [In] is the indium content (%) in the indium gallium nitride quantum well, y₀ is a background condition constant, α_{In} is the doping probability of indium element, εᵢ is a coefficient (J) related to indium doping, k_{B} is the Boltzmann constant (J·K⁻¹), T₀ is the initial epitaxy temperature (K), and T is the epitaxial growth temperature (K). Thus, the growth conditions of the indium gallium nitride quantum wells can be systematically adjusted.

In an example, the method further includes forming multiple indium gallium nitride buffer layers between the end surface and the quantum well layer, with the indium content of the indium gallium nitride buffer layer increasing as the indium gallium nitride buffer layer being farther from the end surface. Thus, the occurrence of cracks in the quantum well layer due to strain accumulation can be decreased, thereby improving the structural quality of the quantum well.

In an example, forming multiple indium gallium nitride buffer layers includes forming two indium gallium nitride buffer layers. Thus, the structural quality of the quantum well can be improved.

In an example, In/Ga flow ratios are 0.5 and 1.67, respectively, while forming the two indium gallium nitride buffer layers. Thus, the structural quality of the quantum well can be further improved.

In an example, the method further includes forming a cover layer on the multiple quantum well layers. Thus, the structural quality of the quantum well can be improved.

In an example, forming multiple quantum well layers includes forming two to five quantum well layers. Thus, the luminous efficiency can be improved.

In an example, an In/Ga flow ratio is 7.5 while forming the indium gallium nitride quantum well. Thus, the structural quality of the quantum well can be improved.

In an example, the growth temperature is in a range of 600° C. to 800° C. Thus, indium gallium nitride quantum well grains emitting lights of different colors can be grown using a single material.

### BRIEF DESCRIPTION OF THE DRAWINGS

The present invention will become more fully understood from the detailed description given hereinafter and the accompanying drawings which are given by way of illustration only, and thus are not limitative of the present invention, and wherein:

FIG. 1 illustrates a schematic cross-sectional view of an embodiment of an indium gallium nitride quantum well structure manufactured by the method of the present invention.

FIG. 2 illustrates a schematic cross-sectional view of another embodiment of an indium gallium nitride quantum well structure manufactured by the method of the present invention.

FIG. 3 illustrates a top scanning electron microscope (SEM) image of an indium gallium nitride quantum well structure sample A manufactured by the method of the present invention.

FIG. 4 illustrates a top SEM image of an indium gallium nitride quantum well structure sample B manufactured by the method of the present invention.

FIG. 5 illustrates a top SEM image of an indium gallium nitride quantum well structure sample C manufactured by the method of the present invention.

FIG. 6 illustrates a top SEM image of an indium gallium nitride quantum well structure sample D manufactured by the method of the present invention.

FIG. 7 illustrates a top SEM image of an indium gallium nitride quantum well structure sample E manufactured by the method of the present invention.

FIG. 8 illustrates a side SEM image of an indium gallium nitride quantum well structure sample A manufactured by the method of the present invention.

FIG. 9 illustrates a side SEM image of an indium gallium nitride quantum well structure sample B manufactured by the method of the present invention.

FIG. 10 illustrates a side SEM image of an indium gallium nitride quantum well structure sample C manufactured by the method of the present invention.

FIG. 11 illustrates a side SEM image of an indium gallium nitride quantum well structure sample D manufactured by the method of the present invention.

FIG. 12 illustrates a side SEM image of an indium gallium nitride quantum well structure sample E manufactured by the method of the present invention.

FIG. 13 illustrates a transmission electron microscope (TEM) image of an indium gallium nitride quantum well structure sample E manufactured by the method of the present invention.

FIG. 14 illustrates a scanning transmission electron microscope (STEM) image of an indium gallium nitride quantum well structure sample E manufactured by the method of the present invention.

FIG. 15 illustrates a STEM image of an indium gallium nitride quantum well structure sample E manufactured by the method of the present invention.

FIG. 16 illustrates an image of photoluminescence spectroscopy of an indium gallium nitride quantum well structure samples A to E manufactured by the method of the present invention.

FIG. 17 illustrates a trend equation of quantum well growth temperature and indium content fitted in accordance with the present invention.

When the terms “front”, “rear”, “left”, “right”, “up”, “down”, “top”, “bottom”, “inner”, “outer”, “side”, and similar terms are used herein, it should be understood that these terms have reference only to the structure shown in the drawings as it would appear to a person viewing the drawings and are utilized only to facilitate describing the invention, rather than restricting the invention.

### DETAILED DESCRIPTION OF THE INVENTION

The term “c-plane” used herein refers to the hexagonal plane on the top surface of a hexagonal prism in the hexagonal crystal system, which can be understood by one skilled in the art.

The method of forming indium gallium nitride quantum well structures of the present invention can be performed by using, for example, molecular beam epitaxy (MBE), plasma-assisted molecular beam epitaxy (PAMBE), etc.

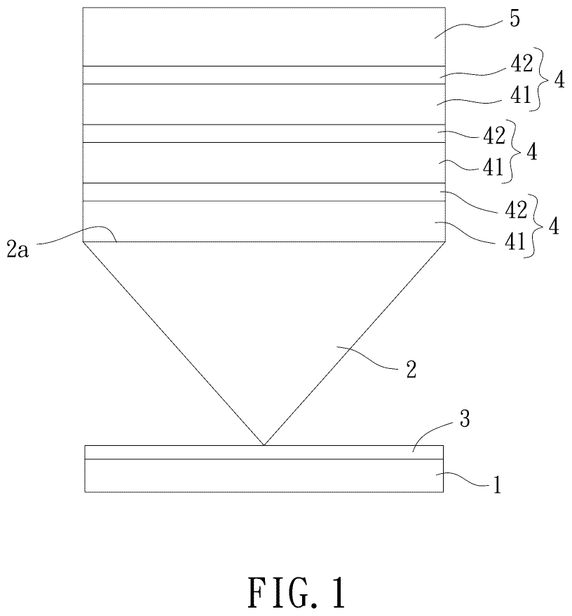

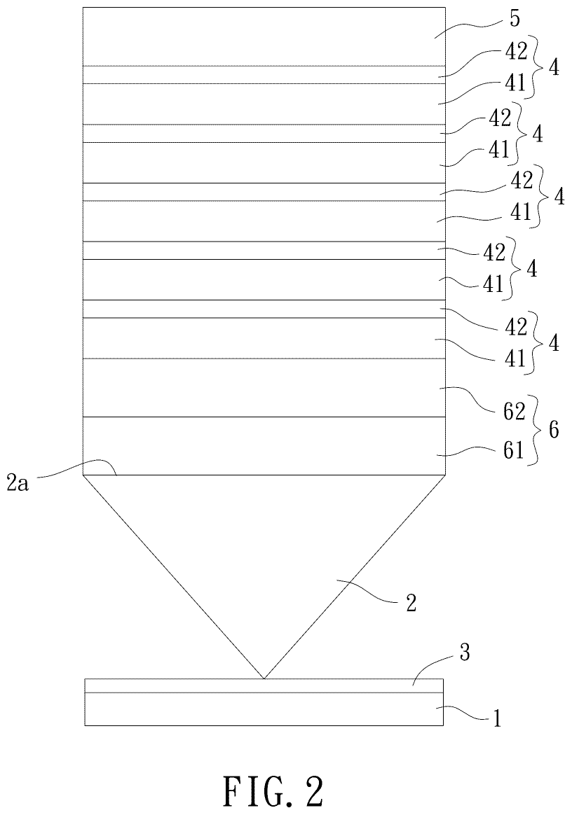

FIG. 1 and FIG. 2 each illustrates a schematic cross-sectional view of an embodiment of an indium gallium nitride quantum well structure manufactured by the method of the present invention. It is noted that the dimension ratios of the structures in the drawings are intended for illustrative purposes and are not drawn to scale. The method of the present invention is discussed below in detail with respect to FIG. 1 and FIG. 2.

The method of the present invention includes: forming a gallium nitride microdisk 2 on a substrate 1. The substrate 1 can be a LiAlO₂ substrate, a LiGaO₂ substrate, or a ZnO substrate, thereby improving the degree of lattice matching between the substrate and other materials (for example, gallium nitride used in subsequent reactions) and increasing the success rate of subsequent processes.

Prior to forming the gallium nitride microdisk 2 on the substrate 1, the substrate 1 may be optionally cleaned to remove potential impurities on the surface of the substrate 1, improving the quality of subsequent epitaxy. For example, acetone, isopropyl alcohol, phosphoric acid solution or deionized water can be used to clean the surface of the substrate 1. Thereafter, the liquid on the surface of the substrate 1 can be dried out using nitrogen gas, and then heated to 770° C. for 10 minutes in an MBE chamber to ensure that the surface of the substrate 1 is clean and the gases are exhausted out. Then, the substrate 1 is set to an operating temperature for the subsequent process.

In one embodiment, forming the gallium nitride microdisk 2 on the substrate 1 can be performed in two steps, thereby obtaining a gallium nitride microdisk with a good lattice structure. For example, a first epitaxy step may be performed on the substrate 1 at a temperature of 600° C. to 650° C. and a N₂/Ga flow ratio of 25 to 75 for 30 to 50 minutes; and a second epitaxy step may be performed on the substrate 1 at a temperature of 600° C. to 650° C. and a N₂/Ga flow ratio of 130 to 150 for 60 to 110 minutes. As shown in FIG. 1, the gallium nitride microdisk 2 is in a form of inverted pyramid and has an end surface 2a.

In one embodiment, it is also possible to form a gallium infiltration layer 3 on the substrate 1 first, and then form the gallium nitride microdisk 2 on the substrate 1 on which the gallium infiltration layer 3 is formed. Since the material properties of the gallium infiltration layer 3 are closer to the gallium nitride forming the gallium nitride microdisk 2, the bonding strength between the substrate 1 and the gallium nitride microdisk 2 can be improved, and the epitaxy success rate of gallium nitride microdisk 2 can be increased. For example, the gallium infiltration layer 3 is formed by providing a gallium-containing vapor for performing epitaxy on the substrate 1 at 630° C. for 5 minutes.

The method of the present invention includes: forming multiple quantum well layers 4 on the end surface 2a, with each quantum well layer 4 including an indium gallium nitride quantum well 41 and a barrier layer 42. The indium gallium nitride quantum well 41 can emit light due to the electroluminescence effect. The barrier layer 42 can block and protect the indium gallium nitride quantum well 41, thereby increasing the lifetime of the indium gallium nitride quantum well 41. In one embodiment, a total of 2 to 5 layers of stacked quantum well layers 4 can be repeatedly formed, thereby utilizing multiple quantum wells to increase luminous efficiency. For example, when forming a total of two quantum well layers 4, an indium gallium nitride quantum well 41, a barrier layer 42, an indium gallium nitride quantum well 41 and a barrier layer 42 can be formed sequentially on the end surface 2a.

The growth of the indium gallium nitride quantum well is carried out at a growth temperature, and the growth temperature is adjusted using a trend equation. The growth temperature is in a range of 480° C. to 810° C. The establishing of the trend equation will be explained in detail in the following paragraph [Establishment of Trend Equation].

Specifically, the forming step of each indium gallium nitride quantum well is as follows: performing an epitaxy under the conditions of a temperature of 480° C. to 810° C., preferably 600° C. to 800° C., an In/Ga flow ratio of 1 to 10, and a duration of 1 to 5 minutes. In one embodiment, the indium gallium nitride quantum well is formed by performing an epitaxy at 670° C. to 720° C. and an In/Ga flow ratio of 7.5 (with the pressure of In being 1.5×10⁻⁷ Torr, the pressure of Ga being 2.0×10⁻⁸ Torr, and the pressure of N₂ being 9.0×10⁻⁶ Torr) for 3 minutes.

The barrier layer 42 may be, for example, an indium gallium nitride barrier layer. The forming step of each barrier layer 42 is as follows: performing an epitaxy under the conditions of a temperature of 480° C. to 810° C., preferably 600° C. to 800° C., an In/Ga flow ratio of 1 to 10, and a duration of 1 to 5 minutes. In one embodiment, the barrier layer 42 is formed by performing an epitaxy at 720° C. and an In/Ga flow ratio of 1.67 (with the pressure of In being 1.0×10⁻⁷ Torr, the pressure of Ga being 6.0×10⁻⁸ Torr, and the pressure of N₂ being 9.0×10⁻⁶ Torr) for 3 minutes.

The method of the present invention may further include: forming a cover layer 5 on the multiple quantum well layer 4. The cover layer 5 can block and protect the multiple quantum well layer 4, thereby increasing the lifetime of the multiple quantum well layer 4. The cover layer 5 may be, for example, an indium gallium nitride cover layer. For example, the cover layer 5 is formed by performing an epitaxy under the conditions of a temperature of 480° C. to 810° C., preferably 600° C. to 800° C., an In/Ga flow ratio of 1 to 10, and a duration of 1 to 7 minutes. In one embodiment, the cover layer 5 is formed by performing an epitaxy at 720° C. and an In/Ga flow ratio of 1.67 (with the pressure of In being 1.0×10⁻⁷ Torr, the pressure of Ga being 6.0×10⁻⁸ Torr, and the pressure of N₂ being 9.0×10⁻⁶ Torr) for 5 minutes.

Referring to FIG. 2, the method of the present invention may further include: forming multiple indium gallium nitride buffer layers 6 between the end surface 2a and the quantum well layer. Among the multiple indium gallium nitride buffer layers 6, the indium content of the indium gallium nitride buffer layer 6 increases as the indium gallium nitride buffer layer 6 is farther from the end surface. This may help reduce the occurrence of cracks in the quantum well layer due to strain accumulation, and improve the quality of the indium gallium nitride quantum well structure, especially the green and red lights indium gallium nitride quantum wells with higher indium contents.

Specifically, the indium gallium nitride buffer layers 6 with different indium contents can be formed by adjusting the indium/gallium flow ratio under a fixed operating temperature and nitrogen flow rate. For example, each indium gallium nitride buffer layer 6 can be formed by performing an epitaxy under the conditions of a temperature of 480° C. to 810° C., preferably 600° C. to 800° C., an In/Ga flow ratio of 0.1 to 5, and a duration of 10 to 30 minutes. Referring to FIG. 2, in one embodiment, a first indium gallium nitride buffer layer 61 is formed by performing an epitaxy on the end surface 2a at 720° C. and an In/Ga flow ratio of 0.5 (wherein the pressure of In is 5.0×10⁻⁸ Torr, the pressure of Ga is 1.0×10⁻⁷ Torr, and the pressure of N₂ is 9.0×10⁻⁶ Torr) for 20 minutes. A second indium gallium nitride buffer layer 62 is then formed by performing an epitaxy on the first indium gallium nitride buffer layer 61 at 720° C. and an In/Ga flow ratio of 1.67 (with the pressure of In being 1.0×10⁻⁷ Torr, the pressure of Ga being 6.0×10⁻⁸ Torr, and the pressure of N₂ being 9.0×10⁻⁶ Torr) for 20 minutes. The indium content of the second indium gallium nitride buffer layer 62 is higher than the first indium gallium nitride buffer layer 61.

[Establishment of Trend Equation] The following experiments were performed to establish a trend equation between the growth temperature and indium content of indium gallium nitride quantum wells.

### Experiment I: Preparation of Samples A to E

Sample A: A sample used for determining the quality of an indium gallium nitride buffer layer. Sample A is prepared by forming a gallium infiltration layer on a LiAlO₂ substrate, and then forming a gallium nitride microdisk using MBE in two stages (first performing an epitaxy at 630° C. and a N₂/Ga flow ratio of 29.0 for 35 minutes, and then performing another epitaxy at 630° C. and a N₂/Ga flow ratio of 138.8 for 7 minutes). Thereafter, form a first indium gallium nitride buffer layer on an end surface of the gallium nitride microdisk (by performing an epitaxy at 720° C. and an In/Ga flow ratio of 0.5 for 20 minutes), and then form a second indium gallium nitride buffer layer (by performing an epitaxy at 720° C. and an In/Ga flow ratio of 1.67 for 20 minutes).

Sample B: A sample used for establishing a trend equation. Sample B is prepared by first preparing Sample A, and then further forming five-layer quantum well layers on the second indium gallium nitride buffer layer, with each quantum well layer including an indium gallium nitride quantum well and a barrier layer. Specifically, an indium gallium nitride quantum well is formed by performing an epitaxy at 720° C. and an In/Ga flow ratio of 7.5 for 3 minutes, and a barrier layer is formed by performing an epitaxy at 720° C. and an In/Ga flow ratio of 1.67 for 3 minutes. The above steps are repeated to form the five quantum well layers. Thereafter, form a cover layer on the five quantum well layers (by performing an epitaxy at 720° C. and an In/Ga flow ratio of 1.67 for 5 minutes).

Sample C: Prepared in the same manner as Sample B except that the growth temperature of the indium gallium nitride quantum well is changed to 700° C.

Sample D: Prepared in the same manner as Sample B except that the growth temperature of the indium gallium nitride quantum well is changed to 680° C.

Sample E: Prepared in the same manner as Sample B except that the growth temperature of the indium gallium nitride quantum well is changed to 670° C.

The conditions for preparing Samples A to E are listed in Table 1 below.

TABLE 1
the conditions for preparing Samples A to E.

| | Sample A | Sample B | Sample C | Sample D | Sample E |
|---|---|---|---|---|---|
| Each layer | In/Ga flow ratio/Growth Temp.(° C.) | | | | |
| First indium | 0.5/720 | 0.5/720 | 0.5/720 | 0.5/720 | 0.5/720 |
| gallium nitride | | | | | |
| buffer layer | | | | | |
| Second indium | 1.67/720 | 1.67/720 | 1.67/720 | 1.67/720 | 1.67/720 |
| gallium nitride | | | | | |
| buffer layer | | | | | |
| Indium gallium | — | 7.5/720 | 7.5/700 | 7.5/680 | 7.5/670 |
| nitride quantum | | | | | |
| well | | | | | |
| (5 layers) | | | | | |
| Barrier layer | — | 1.67/720 | 1.67/720 | 1.67/720 | 1.67/720 |
| Cover layer | — | 1.67/720 | 1.67/720 | 1.67/720 | 1.67/720 |

### Experiment II: Scanning Electron Microscope (SEM) Images

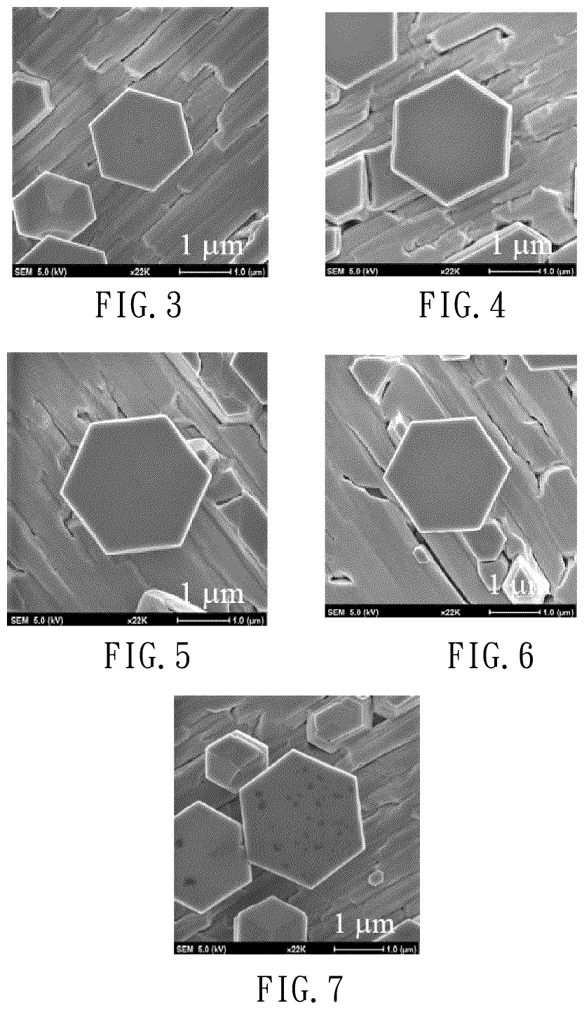

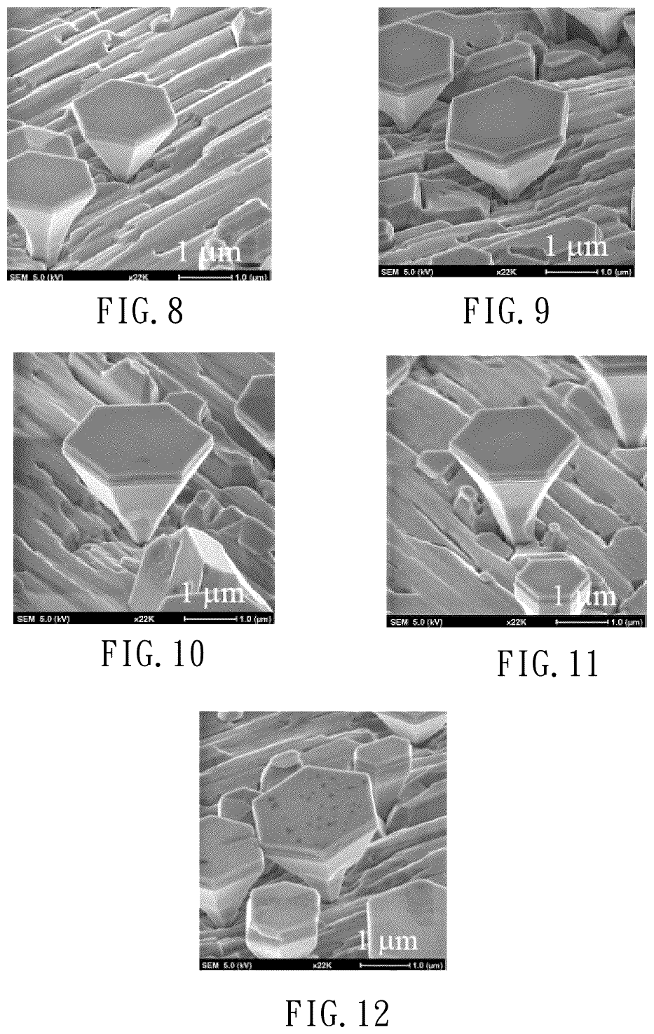

Samples A to E are observed with a SEM to determine the structures of Samples A to E. The results are shown in FIG. 3 to FIG. 12. FIG. 3 to FIG. 7 are top views and FIG. 8 to FIG. 12 are side views. FIG. 3 and FIG. 8 correspond to Sample A, FIG. 4 and FIG. 9 correspond to Sample B, FIG. 5 and FIG. 10 correspond to Sample C, FIG. 6 and FIG. 11 correspond to Sample D, and FIG. 7 and FIG. 12 correspond to Sample E. As shown, the indium gallium nitride quantum well structure of the present invention has a hexagonal three-dimensional c-plane, and the overall structure is in a form of an inverted hexagonal pyramid.

### Experiment III: Transmission Electron Microscope (TEM) Images/Scanning Transmission Electron Microscope (STEM) Images

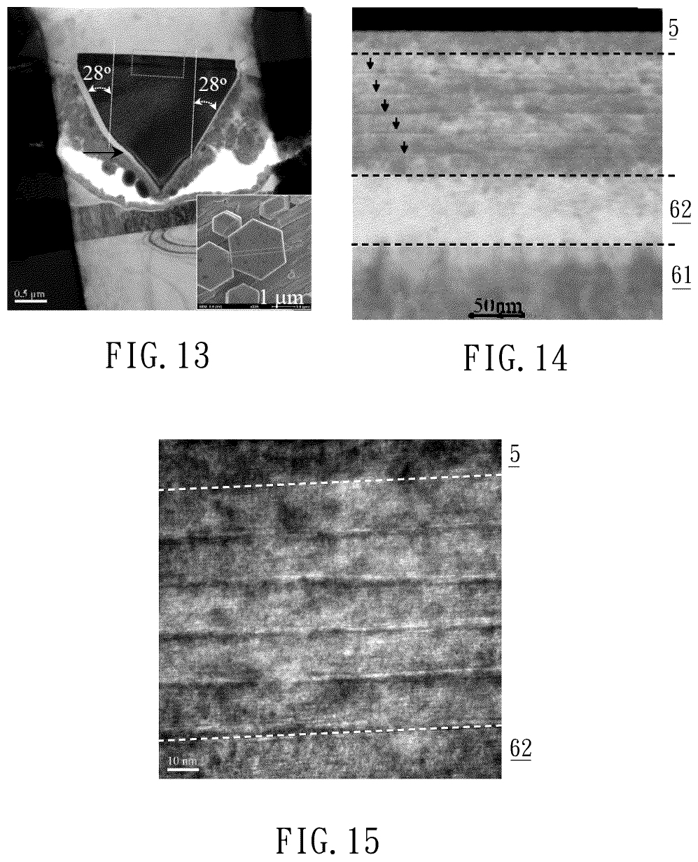

Sample E is observed with a TEM to observe the microstructures of the indium gallium nitride quantum well in detail. The result is shown in the cross-sectional view of FIG. 13. The formation of multiple quantum wells can be observed in the section framed by the rectangle. Moreover, it can be observed that the gallium nitride microdisk forms an inverted pyramid at an angle of 28°. The indium gallium nitride buffer layer also maintains a cone-shaped divergent growth of 28° until the indium gallium nitride quantum well (quantum well layer) is formed. The angle of 28° cannot be maintained due to strain, and the indium gallium nitride buffer layer begins to grow vertically along the c-axis. In addition, referring to the arrow in FIG. 13, it is observed that the indium gallium nitride buffer layer can repair structural defects, maintaining the growth of 28°. This situation can also be observed in FIG. 12. Furthermore, the framed section in FIG. 13 is observed using a scanning transmission electron microscope. The results are shown in FIG. 14 and FIG. 15. In FIG. 14, a first indium gallium nitride buffer layer 61, a second indium gallium nitride buffer layer 62, and five quantum well layers formed on the second indium gallium nitride buffer layer 62 (as indicated by the arrow in FIG. 14) are observed. In FIG. 15, it can be observed that a multiple quantum well structure with a stack of indium gallium nitride quantum wells and barrier layers is formed between the second indium gallium nitride buffer layer 62 and the cover layer 5. These images indicate that the indium gallium nitride quantum well structure produced by the method of the present invention has a good growing quality.

### Experiment IV: Photoluminescence Spectral Analysis

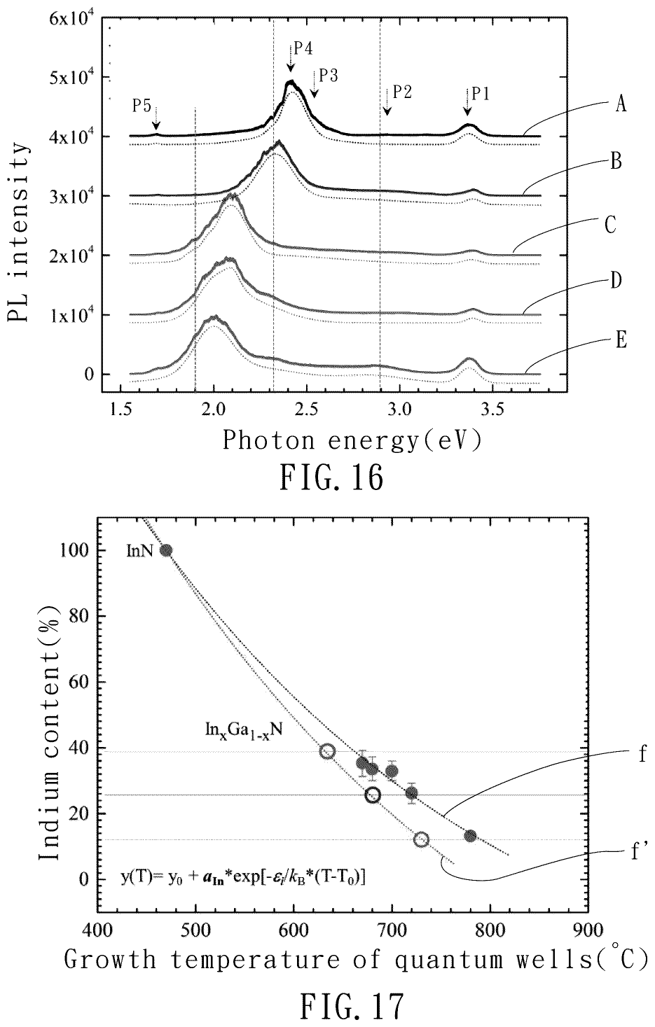

For analyzing the optical properties of indium gallium nitride quantum wells, photoluminescence spectral analysis is performed on Samples A to E using a 325 nm He-Cd laser as the excitation light source at room temperature. The results are shown in FIG. 16. The solid lines A to E represent the full fluorescence measurement spectrum of samples A-E. The nonlinear curve fitting method of Gaussian function is used to fit the spectra, and the best fitting results are shown as dotted lines. For each sample, two main peaks were detected (as indicated by arrows P1 and P4, referring to peaks P1 and P4, respectively). The peak P1 located at (3.370±0.0001) eV does not move for the different samples, so it is deduced that the peak P1 is the light emitted by the gallium nitride microdisk. For sample A, the amplitude of peak P4 is one order of magnitude larger than that of wave peak P1, and the photon energy is (2.422±0.001) eV, which is consistent with the green color visible to the naked eye when Sample A undergoes photoluminescence. Therefore, it is deduced that the main peak P4 of Sample A is the light emitted by the indium gallium nitride buffer layer. Similarly, the photon energies of the main peaks P4 for Samples B to E are (2.332±0.001) eV, (2.092±0.001) eV, (2.072±0.001) eV, and (1.995±0.001) eV, which are emitted by InGaN quantum wells. Regarding the remaining peaks, peaks P2 and P3 indicated by arrows P2 and P3 are caused by impurities or structural defects, and peak P5 indicated by arrow P5 is the secondary diffraction of peak P1.

The respective indium content in each sample can be calculated from the above photon energy using Vegard's law. As the calculation results, the indium content in the indium gallium nitride buffer layer of Sample A is 23.8%; the indium content in the indium gallium nitride quantum wells of Samples B, C, D and E are 26.2%, 32.9%, 33.5% and 35.3%, respectively. As used herein, “the indium content in the indium gallium nitride quantum well” refers to the indium element relative to the sum (in percentage) of indium element and gallium element. The above results show that the higher the growth temperature of the indium gallium nitride quantum well, the lower the indium content (i.e., the higher the gallium content). This is because in the molecular beam epitaxy method, the growth of the epitaxial layer is mainly controlled by the temperature of the growth surface (i.e., the growth temperature). Therefore, under the same temperature conditions, gallium atoms with smaller mass and atomic size will be more active than indium atoms. That is, a higher growth temperature is beneficial to the growth of gallium.

### Experiment V: Curve Fitting

For establishing a mechanism that can control the indium content by adjusting the growth temperature of the indium gallium nitride quantum well, the quantum well growth temperature and indium content data of Samples B to E above are used to perform curve fitting, with the data of two samples In_{0.13}Ga_{0.87}N (780° C., indium content 13%) and InN (470° C., indium content 100%) prepared in previous research used as interpolation. The result is shown in the function curve f on the right side of FIG. 17, and the temperature on the x-axis is expressed in the more commonly used Celsius temperature scale. The trend equation of the best fitting result is as follows:

$$[ In ] = y ( T ) = {y}_{0} + {α}_{In} * exp [ - {ε}_{i} / {k}_{B} * ( T - {T}_{0} ) ] ,$$

in which [In] is the indium content (%) in the indium gallium nitride quantum well, y₀ is the background condition constant, α_{In} is the doping probability of indium element, εᵢ is a coefficient (J) related to indium doping, k_{B} is the Boltzmann constant (J·K⁻¹), T₀ is the initial epitaxy temperature (K), and T is the epitaxial growth temperature (K). In the function curve f fitted by Samples B to E and the above two interpolations, y₀ is −40.95; α_{In} is 7.824×10⁷; and εᵢ is −8.517×10⁻¹⁹. It can be understood from the above trend equation that the indium content decreases as the quantum well growth temperature increases.

Using the above trend equation, the indium content in the indium gallium nitride quantum well can be controlled by changing the epitaxial growth temperature, thereby obtaining the light with a desired color. In addition, the α_{In} and εᵢ values in the function curve can be set to fixed values. When preparing samples under different epitaxial conditions, by substituting these conditions into the trend equation with the fixed values of α_{In} and εᵢ, the function curve of the quantum well growth temperature and indium content under the epitaxial conditions can be quickly obtained, thereby efficiently obtaining the corresponding relationship between quantum well growth temperature and indium content.

For example, using different epitaxy conditions from the above Samples B to E, a blue light indium gallium nitride quantum well structure is prepared as follows: (1) forming a gallium nitride microdisk on a LiAlO₂ substrate by performing an epitaxy at 630° C., a pressure of N₂ of 9.0×10⁻⁶ Torr, and a pressure of Ga of 1.25×10⁻⁷ Torr for 40 minutes; (2) forming an indium gallium nitride layer on the gallium nitride microdisk by performing an epitaxy at 630° C., a pressure of N₂ of 9.0×10⁻⁶ Torr, and a pressure of Ga of 6.50×10⁻⁸ Torr for 100 minutes; (3) forming three indium gallium nitride quantum well layers on the indium gallium nitride layer, with each quantum well layer formed by performing an epitaxy at 730° C., a pressure of In of 5.40×10⁻⁸ Torr, a pressure of Ga of 5.40×10⁻⁸ Torr, and a pressure of N₂ of 9.0×10⁻⁹ Torr for 90 seconds; and (4) forming a gallium nitride cover layer on the three indium gallium nitride quantum well layers by performing an epitaxy at 770° C., a pressure of N₂ of 9.0×10⁻⁶ Torr, and a pressure of Ga of 1.25×10⁻⁷ Torr for 3 minutes. Photoluminescence spectral analysis is performed on the blue light indium gallium nitride quantum well structure prepared above. As a result, the peak value of the main peak is (2.935±0.001) eV. The indium content of the indium gallium nitride quantum well is calculated to be 12% using the formula of Vegard's law.

The α_{In} value (7.824×10⁷) and εᵢ value (−8.517×10⁻¹⁹) obtained from the function curve f of the above Samples B to E are used as fixed values. Accordingly, the function curve f′ of quantum well growth temperature and indium content under this epitaxial condition (the curve on the left side in FIG. 17) can be obtained by substituting the above data of blue light indium gallium nitride quantum well (quantum well growth temperature of 730° C., indium content of 12%) and InN (470° C., indium content of 100%) into the trend equation with the fixed values of α_{In} and εᵢ. In this way, the growth conditions of the indium gallium nitride quantum well can be systematically adjusted based on the function curve f′. For example, according to Vegard's law, the indium contents in green and red indium gallium nitride quantum wells are approximately 26% and 39%, respectively. Therefore, as shown in FIG. 17, under these epitaxial conditions, the growth temperatures can be set to 680° C. and 630° C., respectively, to obtain green and red light indium gallium nitride quantum wells.

In summary, the method of forming an indium gallium nitride quantum well structure according to the present invention may involve setting the flow ratio of indium and gallium to a fixed value when forming the indium gallium nitride quantum well, and controlling the indium content in the formed indium gallium nitride quantum well by adjusting the growth temperature, thereby making indium gallium nitride quantum wells emit lights of different colors. Accordingly, the method of forming an indium gallium nitride quantum well structure according to the present invention provides an effect of growing indium gallium nitride quantum well grains emitting lights of different colors using a single material.

Although the present invention has been described with respect to the above preferred embodiments, these embodiments are not intended to restrict the present invention. Various changes and modifications on the above embodiments made by any person skilled in the art without departing from the spirit and scope of the present invention are still within the technical category protected by the present invention. Accordingly, the scope of the present invention shall include the literal meaning set forth in the appended claims and all changes which come within the range of equivalency of the claims. Furthermore, in a case that several of the above embodiments can be combined, the present invention includes the implementation of any combination.

What is claimed is:

1. A method of forming an indium gallium nitride quantum well structure, comprising:
forming a gallium nitride microdisk on a substrate, wherein the gallium nitride microdisk is in a form of an inverted pyramid and has an end surface; and
forming multiple quantum well layers on the end surface, wherein each quantum well layer includes an indium gallium nitride quantum well and a barrier layer,
wherein the indium gallium nitride quantum well is grown at a growth temperature in a range of 480° C. to 810° C., and wherein the growth temperature is adjusted using a trend equation.

2. The method of forming the indium gallium nitride quantum well structure as claimed in claim 1, wherein the trend equation is
$$[ In ] = y ( T ) = {y}_{0} + {α}_{In} * exp [ - {ε}_{i} / {k}_{B} * ( T - {T}_{0} ) ] ,$$
wherein [In] is the indium content (%) in the indium gallium nitride quantum well, y₀ is a background condition constant, α_{In} is the doping probability of indium element, εᵢ is a coefficient (J) related to indium doping, k_{B} is the Boltzmann constant (J·K⁻¹), T₀ is the initial epitaxy temperature (K), and T is the epitaxial growth temperature (K).

3. The method of forming the indium gallium nitride quantum well structure as claimed in claim 1, further comprising forming multiple indium gallium nitride buffer layers between the end surface and the quantum well layer, wherein an indium content of the indium gallium nitride buffer layer increases as the indium gallium nitride buffer layer is farther from the end surface.

4. The method of forming the indium gallium nitride quantum well structure as claimed in claim 3, wherein forming multiple indium gallium nitride buffer layers includes forming two indium gallium nitride buffer layers.

5. The method of forming the indium gallium nitride quantum well structure as claimed in claim 4, wherein In/Ga flow ratios are 0.5 and 1.67, respectively, while forming the two indium gallium nitride buffer layers.

6. The method of forming the indium gallium nitride quantum well structure as claimed in claim 1, further comprising forming a cover layer on the multiple quantum well layers.

7. The method of forming the indium gallium nitride quantum well structure as claimed in claim 1, wherein forming multiple quantum well layers includes forming two to five quantum well layers.

8. The method of forming the indium gallium nitride quantum well structure as claimed in claim 1, wherein an In/Ga flow ratio is 7.5 while forming the indium gallium nitride quantum well.

9. The method of forming the indium gallium nitride quantum well structure as claimed in claim 1, wherein the growth temperature is in a range of 600° C. to 800° C.
